(19) United States
(12) Patent Application Publication
(10) Pub. No.: US 2026/0032953 A1
(43) Pub. Date: Jan. 29, 2026

(54) ARRAY SUBSTRATE AND DISPLAY PANEL

(71) Applicant: Guangzhou China Star Optoelectronics Semiconductor Display Technology Co., Ltd., Guangzhou (CN)

(72) Inventors: Meinan LI, Guangzhou (CN); Yuanjun HSU, Guangzhou (CN); Daobing HU, Guangzhou (CN); Yanrui LIN, Guangzhou (CN)

(21) Appl. No.: 18/814,903

(22) Filed: Aug. 26, 2024

(30) Foreign Application Priority Data
Jul. 26, 2024 (CN) 202411018866.5

(51) Int. Cl. H01L 29/786; H01L 27/12

(52) U.S. Cl. CPC H10D 30/6713; H10D 30/6723; H10D 30/6755; H10D 86/423; H10D 86/441; H10D 86/60

(57) ABSTRACT

An array substrate and a display panel are provided. The array substrate includes a substrate and a first conductive layer, a first insulating layer, a semiconductor layer, and a third conductive layer. The first conductive layer includes a source electrode and a light shielding electrode arranged at intervals. The semiconductor layer includes a channel part and a source contact part. A part of the source contact part is disposed inside the first via hole and connected to the source electrode. The third conductive layer includes a first auxiliary electrode corresponding to the source contact part. The first auxiliary electrode is connected to at least the source contact part located inside the first via hole. An orthographic projection of the source contact part located inside the first via hole on the substrate is within a range of an orthographic projection of the first auxiliary electrode on the substrate.

### CROSS-REFERENCE TO RELATED APPLICATION

This application claims priority to Chinese Patent Application No. 202411018866.5, filed on Jul. 26, 2024, the disclosure of which is incorporated herein by reference in its entirety.

### TECHNICAL FIELD

The present application relates to a technical field of display, and in particular, to an array substrate and a display panel.

### BACKGROUND

In a technical field of display, thin film transistor (TFT) array substrates are important component parts of display panels. The manufacture of a TFT array substrate involves the use of a plurality of photo masks. The more the photo masks are used, the longer an overall process flow of the TFT array substrate, and the greater the difficulty and the higher the costs. In order to reduce the number of the photo masks to be used, a source electrode of a TFT may be disposed below a semiconductor layer, and the semiconductor layer overlaps with the source electrode below. However, it is easy to cause poor overlapping at an overlapping position between the semiconductor layer and the source electrode.

### SUMMARY

In one aspect, the present application provides an array substrate including a substrate, a first conductive layer, a semiconductor layer, a second insulating layer, a second conductive layer, a planarization layer, and a third conductive layer disposed on the substrate. The first conductive layer is disposed on a side of the substrate and includes a source electrode and a light shielding electrode arranged at intervals. The first insulating layer is disposed on a side of the first conductive layer away from the substrate and includes a first via hole corresponding to the source electrode. The semiconductor layer is disposed on a side of the first insulating layer away from the substrate. The semiconductor layer includes a channel part and a source contact part located at a side of the channel part. A part of the source contact part is disposed inside the first via hole and connected to the source electrode, and the channel part corresponds to the light shielding electrode. The second insulating layer is disposed on the semiconductor layer and corresponds to the channel part. The second conductive layer is disposed on the second insulating layer and includes a gate electrode. The planarization layer is disposed on a side of the second conductive layer away from the substrate and includes a second via hole corresponding to the source contact part. The third conductive layer is disposed on a side of the planarization layer away from the substrate and includes a first auxiliary electrode corresponding to the source contact part. The first auxiliary electrode is connected to at least the source contact part located inside the first via hole. An orthographic projection of the source contact part located inside the first via hole on the substrate is within a range of an orthographic projection of the first auxiliary electrode on the substrate.

In another aspect, the present application provides a display panel including the array substrate mentioned above.

### BRIEF DESCRIPTION OF THE DRAWINGS

In order to more clearly explain technical solutions in specific embodiments of the present application or the prior art, the drawings needed to be used in the description of the specific embodiments or the prior art will be briefly introduced below. It is obvious that the drawings in the following description illustrate some embodiments of the present application. For those of ordinary skill in the art, other drawings may be obtained based on these drawings without creative efforts.

FIG. 1 is a first schematic cross-sectional structural view of an array substrate according to an embodiment of the present application.

FIG. 2 is a second schematic cross-sectional structural view of the array substrate according to an embodiment of the present application.

FIG. 3 is a third schematic cross-sectional structural view of the array substrate according to an embodiment of the present application.

FIG. 4 is a fourth schematic cross-sectional structural view of the array substrate according to an embodiment of the present application.

FIG. 5 is a fifth schematic cross-sectional structural view of the array substrate according to an embodiment of the present application.

FIG. 6 is a sixth schematic cross-sectional structural view of the array substrate according to an embodiment of the present application.

FIG. 7 is a seventh schematic cross-sectional structural view of the array substrate according to an embodiment of the present application.

FIG. 8 is an eighth schematic cross-sectional structural view of the array substrate according to an embodiment of the present application.

### DETAILED DESCRIPTION

The following description of every embodiment with reference to accompanying drawings is used to exemplify a specific embodiment which may be carried out in the present application. Directional terms mentioned in the present application, such as “top”, “bottom”, “front”, “back”, “left”, “right”, “inside”, “outside”, “side” etc., are only used with reference to orientations of the accompanying drawings. Therefore, the used directional terms are intended to illustrate, but not to limit, the present application. In the accompanying drawings, units with similar structures are indicated by a same number. In the accompanying drawings, the thickness of some layers and regions has been exaggerated for clarity and ease of description. That is, the dimension and thickness of each of the elements in the accompanying drawings are arbitrarily shown, which are not been limited by the present application herein.

In one aspect, the present application provides an array substrate including a substrate, a first conductive layer, a semiconductor layer, a second insulating layer, a second conductive layer, a planarization layer, and a third conductive layer disposed on the substrate. The first conductive layer is disposed on a side of the substrate and includes a source electrode and a light shielding electrode arranged at intervals. The first insulating layer is disposed on a side of the first conductive layer away from the substrate and includes a first via hole corresponding to the source electrode. The semiconductor layer is disposed on a side of the first insulating layer away from the substrate. The semiconductor layer includes a channel part and a source contact part located at a side of the channel part. A part of the source contact part is disposed inside the first via hole and connected to the source electrode, and the channel part corresponds to the light shielding electrode. The second insulating layer is disposed on the semiconductor layer and corresponds to the channel part. The second conductive layer is disposed on the second insulating layer and includes a gate electrode. The planarization layer is disposed on a side of the second conductive layer away from the substrate and includes a second via hole corresponding to the source contact part. The third conductive layer is disposed on a side of the planarization layer away from the substrate and includes a first auxiliary electrode corresponding to the source contact part. The first auxiliary electrode is connected to at least the source contact part located inside the first via hole. An orthographic projection of the source contact part located inside the first via hole on the substrate is within a range of an orthographic projection of the first auxiliary electrode on the substrate.

In one embodiment, the first auxiliary electrode is disposed inside the second via hole and the first via hole and connected to the source contact part, and the third conductive layer further includes a pixel electrode.

In one embodiment, the first auxiliary electrode is disposed inside the second via hole and the first via hole and connected to the source contact part, and the third conductive layer further includes a common electrode.

In one embodiment, the array substrate further includes a third third insulating layer and a fourth conductive layer. The third insulating layer is disposed on a side of the third conductive layer away from the substrate and includes a third via hole corresponding to the source contact part. The fourth conductive layer is disposed on a side of the third insulating layer away from the substrate and includes a second auxiliary electrode and a pixel electrode. The second auxiliary electrode is located inside the second via hole and the third via hole and connected to the first auxiliary electrode.

In one embodiment, an inner diameter dimension of the second via hole is greater than an inner diameter dimension of the third via hole, and the inner diameter dimension of the third via hole is greater than an inner diameter dimension of the first via hole.

In one embodiment, the array substrate further includes a fourth insulating layer. The fourth insulating layer is disposed on a side of the gate electrode away from the substrate and includes a fourth via hole corresponding to the source contact part. The first auxiliary electrode is further disposed inside the fourth via hole. The planarization layer is disposed on a side of the fourth insulating layer away from the substrate. An inner diameter dimension of the second via hole is greater than an inner diameter dimension of the fourth via hole.

In one embodiment, the first conductive layer further includes a first bridge electrode, and the first insulating layer further includes a fifth via hole and a sixth via hole corresponding to the first includes electrode. The semiconductor layer further includes a drain contact part located at a side of the channel part away from the source contact part. A part of the drain contact part is disposed inside the fifth via hole and connected to the first bridge electrode. The planarization layer further includes a seventh via hole corresponding to the first bridge electrode. The pixel electrode is located inside the seventh via hole and the sixth via hole and connected to the first bridge electrode.

In one embodiment, the third conductive layer further includes a third auxiliary electrode. The planarization layer further includes an eighth via hole corresponding to the drain contact part. The third auxiliary electrode is disposed inside the eighth via hole and connected to the drain contact part. An orthographic projection of the drain contact part located inside the fifth via hole on the substrate is within a range of an orthographic projection of the third auxiliary electrode on the substrate.

In one embodiment, the first conductive layer further includes a first signal line, and the second conductive layer further includes a second signal line. The planarization layer further includes a ninth via hole corresponding to the first signal line and a tenth via hole corresponding to the second signal line. The array substrate further includes a second bridge electrode arranged in the same layer as the first auxiliary electrode. One part of the second bridge electrode is disposed inside the ninth via hole and connected to the first signal line, and the other part of the second bridge electrode is disposed inside the tenth via hole and connected to the second signal line.

In one embodiment, the array substrate further includes a fourth auxiliary electrode connected to the first signal line. The second bridge electrode is connected to the fourth auxiliary electrode. the fourth auxiliary electrode is arranged in the same layer as the semiconductor layer.

In one embodiment, the array substrate further includes an antioxidant layer at least disposed at a connection position between the semiconductor layer and the first conductive layer.

In another aspect, the present application provides a display panel, which includes the array substrate mentioned above.

The beneficial effects of the present application are illustrated as follows. In the array substrate and the display panel provided by the present application, the array substrate includes the substrate and the substrate, the first conductive layer, the semiconductor layer, the second insulating layer, the second conductive layer, the planarization layer, and the third conductive layer disposed on the substrate. The first conductive layer is disposed on the side of the substrate and includes the source electrode and the light shielding electrode arranged at intervals. The semiconductor layer includes the channel part and the source contact part located at the side of the channel part. The part of the source contact part is disposed inside the first via hole and connected to the source electrode. The third conductive layer is disposed on the side of the planarization layer away from the substrate and includes the first auxiliary electrode corresponding to the source contact part. The first auxiliary electrode is connected to at least the source contact part located inside the first via hole. The orthographic projection of the source contact part located inside the first via hole on the substrate is within the range of the orthographic projection of the first auxiliary electrode on the substrate, so that the first auxiliary electrode can completely cover the source contact part located inside the first via hole. As such, the first auxiliary electrode can fill a position where the source contact part is broken when the source contact part climbs and breaks inside the first via, so that the source contact part is continuous inside the first via, thereby enhancing an overlapping reliability between the source contact part and source electrode, and improving a problem of poor overlapping between the semiconductor layer and the source electrode.

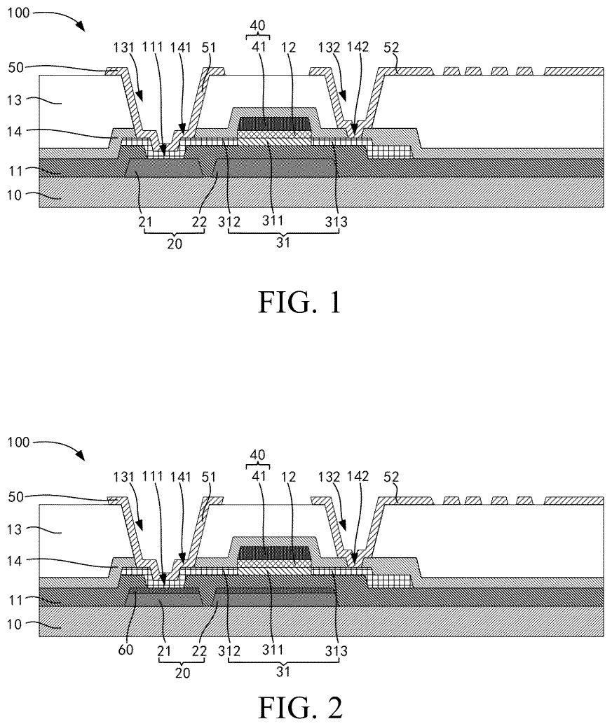

Referring to FIG. 1, FIG. 1 is a first schematic cross-sectional structural view of an array substrate according to an embodiment of the present application. The present application provides an array substrate 100, which includes a substrate 10 and a first transistor disposed on the substrate 10. The first transistor includes a source electrode 21, a semiconductor layer 31, and a gate electrode 41. The array substrate 100 further includes a first conductive layer 20, a first insulating layer 11, a second insulating layer 12, a second conductive layer 40, a planarization layer 13, and a third conductive layer 50. The first conductive layer 20 is disposed on a side of the substrate 10 and includes the source electrode 21 of the first transistor and a light shielding electrode. The first insulating layer 11 is disposed on a side of the first conductive layer 20 away from the substrate 10 and includes a first via hole 111 corresponding to the source electrode 21. The semiconductor layer 31 is disposed on a side of the first insulating layer 11 away from the substrate 10. The semiconductor layer 31 includes a channel part 311 and a source contact part 312 located at a side of the channel part 311. The gate electrode 41 corresponds to the channel part 311. A part of the source contact part 312 is disposed inside the first via hole 111 and connected to the source electrode 21. The channel part 311 corresponds to the light shielding electrode 22. The second insulating layer 12 is disposed on a side of the semiconductor layer 31 away from the substrate 10 and corresponds to the channel part 311. The second conductive layer 40 is disposed on the second insulating layer 12 and includes the gate electrode 41. The planarization layer 13 is disposed on a side of the second conductive layer 40 away from the substrate 10 and includes a second via hole 131 corresponding to the source contact part 312. The third conductive layer 50 is disposed on a side of the planarization layer 13 away from the substrate 10 and includes a first auxiliary electrode 51 corresponding to the source contact part 312. The first auxiliary electrode 51 is connected to at least the source contact part 312 located inside the first via hole 111. An orthographic projection of the source contact part 312 located inside the first via hole 111 on the substrate 10 is within a range of an orthographic projection of the first auxiliary electrode 51 on the substrate 10, so that the first auxiliary electrode 51 completely covers the source contact part 312 located inside the first via hole 111. As such, the first auxiliary electrode 51 can fill a position where the source contact part 312 is broken when the source contact part 312 climbs and breaks inside the first via 111, so that the source contact part 312 is continuous inside the first via 111, thereby enhancing an overlapping reliability between the source contact part 312 and source electrode 21, and improving a problem of poor overlapping between the semiconductor layer 31 and the source electrode 21.

In this embodiment, the substrate 10 may be a rigid substrate or a flexible substrate. The rigid substrate may be selected from one of a glass substrate, a quartz substrate, or a silicon wafer. The flexible substrate 10 may be selected from one of a polyimide (PI) film or an ultra-thin glass film. When the substrate 10 is the polyimide film, moisture or oxygen may penetrate into the substrate 10 more easily than the glass substrate. In order to prevent this situation above, a buffer layer including a single-layer or multilayer structure including silicon oxide or silicon nitride may be disposed on the substrate 10.

The first transistor is disposed on the substrate 10. The first transistor may be a thin film transistor. The first transistor includes the source electrode 21, the semiconductor layer 31, and the gate electrode 41. The semiconductor layer 31 is disposed on a side of the source electrode 21 away from the substrate 10. The gate electrode 41 is disposed on the side of the semiconductor layer 31 away from the substrate 10. The semiconductor layer 31 includes the channel part 311 and the source contact part 312 located at the side of the channel part 311. The semiconductor layer 31 further includes a drain contact part 313 located at a side of the channel part 311 away from the source contact part 312. That is, the drain contact part 313 and the source contact part 312 are located on opposite sides of the channel part 311. The gate electrode 41 corresponds to the channel part 311. An orthographic projection of the gate electrode 41 on the substrate 10 coincides with an orthographic projection of the channel part 311 on the substrate 10.

The first conductive layer 20 is disposed on the substrate 10. The first conductive layer 20 includes the source electrode 21 of the first transistor. In one embodiment, the first conductive layer 20 further includes the light-shielding electrode 22. The light-shielding electrode 22 and the source electrode 21 are arranged at intervals, and the light-shielding electrode 22 is insulated from the source electrode 21. The light shielding electrode 22 at least corresponds to the channel part 311 to shield the channel part 311 from light, thereby reducing a photogenerated leakage current of the first transistor. The first conductive layer 20 may be made of low-resistance materials such as Al, Ti, Mo, Cu, Ni, or an alloy thereof, or a plurality of layers or a single layer of materials having high anti-corrosion properties. In this embodiment, the first conductive layer 20 may be a triple layer of Ti/Cu/Ti, Ti/Ag/Ti, Ti/Al/Ti, or Mo/Al/Mo.

The first insulating layer 11 covers the first conductive layer 20 and the substrate 10. The first insulating layer 11 is provided with the first via hole 111 at a position corresponding to the source electrode 21. The first via hole 111 penetrates through the first insulating layer 11 to expose at least a part of the source electrode 21. A thickness of the first insulating layer 11 ranges from 3000 angstroms to 5000 angstroms. A depth of the first via hole 111 is equal to the thickness of the first insulating layer 11. That is, the depth of the first via hole 111 ranges from 3000 angstroms to 5000 angstroms, such as 3000 angstroms, 3500 angstroms, 4000 angstroms, 4500 angstroms, or 5000 angstroms. The first insulating layer 11 is made of an inorganic material, such as a plurality of layers or a single layer including at least one of tetraethyl orthosilicate, silicon nitride, silicon oxide, etc.

The semiconductor layer 31 is disposed on the side of the first insulating layer 11 away from the substrate 10. Both the source contact part 312 and the drain contact part 313 of the semiconductor layer 31 are formed by conducting the semiconductor layer 31, so that conduct areas are formed by the source contact part 312 and the drain contact part 313 of the semiconductor layer 31. The source contact part 312 is located on a part of the first insulating layer 11 and located inside the first via hole 111. The source contact part 312 located inside the first via hole 111 covers a hole wall of the first via hole 111 and the source electrode 21 exposed by the first via hole 111 to be connected to the source electrode 21. A thickness of the semiconductor layer 31 ranges from 200 angstroms to 400 angstroms, such as 200 angstroms, 220 angstroms, 250 angstroms, 280 angstroms, 300 angstroms, 350 angstroms, 380 angstroms, or 400 angstroms. The semiconductor layer 31 is made of a semiconductor material such as polysilicon or a metal oxide.

The array substrate 100 further includes a second insulating layer 12 and a second conductive layer 40. The second insulating layer 12 is disposed on the side of the semiconductor layer 31 away from the substrate 10 and corresponds to the channel part 311. The second insulating layer 12 is made of an inorganic material, such as a plurality of layers or a single layer including at least one of tetraethyl orthosilicate, silicon nitride, silicon oxide, etc. The second conductive layer 40 is disposed on a side of the second insulating layer 12 away from the substrate 10. The second conductive layer 40 includes the gate electrode 41 of the first transistor, and the gate electrode 41 corresponds to the second insulating layer 12. The second conductive layer 40 may be made of a low-resistance material such as Al, Ti, Mo, Cu, Ni, or an alloy thereof, or a plurality of layers or a single layer of a material having high anti-corrosion properties. In this embodiment, the first conductive layer 20 may be a triple layer of Ti/Cu/Ti, Ti/Ag/Ti, Ti/Al/Ti, or Mo/Al/Mo.

The array substrate 100 further includes the planarization layer 13 disposed on the side of the semiconductor layer 31 away from the substrate 10. The planarization layer 13 includes a second via hole 131 corresponding to the source contact part 312. The second via hole 131 penetrates through the planarization layer 13. The second via hole 131 corresponds to the first via hole 111 and is communicated with the first via hole 111. The planarization layer 13 is made of an organic material. In this embodiment, the planarization layer 13 may be made of a resin, such as polyacrylate, polyimide, or a silica-based organic material. The third conductive layer 50 is disposed on the side of the planarization layer 13 away from the substrate 10. The first auxiliary electrode 51 formed by the third conductive layer 50 is disposed inside the second via hole 131 and the first via hole 111 and connected to the source contact part 312. The third conductive layer 50 may be made of a transparent conductive material, such as indium tin oxide (ITO), indium zinc oxide (IZO), zinc oxide (ZnO), indium oxide (In₂O₃), etc.

Specifically, the first auxiliary electrode 51 covers a part of the planarization layer 13, a hole wall of the second via hole 131, a part of the source contact part 312, and the source contact part 312 located inside the first via hole 111, so as to be connected to at least the source contact part 312 located inside the first via hole 111. Furthermore, the orthographic projection of the source contact part 312 located inside the first via hole 111 on the substrate 10 is located within the range of the orthographic projection of the first auxiliary electrode 51 on the substrate 10, so that the first auxiliary electrode 51 completely covers the source contact part 312 located inside the first via hole 111. As such, without increasing the thickness of the semiconductor layer 31 and/or reducing the thickness of the first insulating layer 11, or increasing an inner diameter dimension of the first via hole 111, the first auxiliary electrode 51 can fill the position where the source contact part 312 is broken even if the source contact part 312 climbs and breaks inside the first via 111, so that the source contact part 312 is continuous inside the first via hole 111, thereby enhancing the overlap reliability between the source contact part 312 and the source electrode 21, and improving the problem of poor overlapping between the semiconductor layer 31 and the source electrode 21.

In some embodiments, an inner diameter dimension of the second via hole 131 is greater than the inner diameter dimension of the first via hole 111. In this embodiment, an opening size of an opening of the second via hole 131 on a side adjacent to the first insulating layer 11 is greater than an opening size of an opening of the first via hole 111 on a side adjacent to the planarization layer 13, so that an orthographic projection of the second via hole 131 on the substrate 10 completely covers the orthographic projection of the first via hole 111 on the substrate 10, and a stepped structure can be formed by the second via hole 131 and the first via hole 111, thereby improving a climbing stability of the first auxiliary electrode 51 inside the second via hole 131 and the first via hole 111. Longitudinal cross-sectional shapes of the second via hole 131 and the first via hole 111 are both inverted trapezoidal.

The third conductive layer 50 further includes a pixel electrode 52 connected to the drain contact part 313 of the semiconductor layer 31. Specifically, the planarization layer 13 is provided with a first other via hole 132 corresponding to the drain contact part 313 of the semiconductor layer 31. The first other via hole 132 penetrates through the planarization layer 13 and exposes a part of the drain contact part 313. A part of the pixel electrode 52 is located inside the first other via hole 132 and connected to the drain contact part 313.

In some embodiments, the array substrate 100 further includes a fourth insulating layer 14 disposed on a side of the gate electrode 41 away from the substrate 10. In this embodiment, the fourth insulating layer 14 covers the gate electrode 41, a part of the source contact part 312, a part of the drain contact part 313, and a part of the first insulating layer 11. The fourth insulating layer 14 includes a fourth via hole 141 corresponding to the source contact part 312. The first auxiliary electrode 51 is further located inside the fourth via hole 141. The fourth insulating layer 14 is made of an inorganic material, such as a plurality of layers or a single layer including at least one of tetraethyl orthosilicate, silicon nitride, silicon oxide, etc. The planarization layer 13 is disposed on a side of the fourth insulating layer 14 away from the substrate 10. In this embodiment, the planarization layer 13 covers the fourth insulating layer 14. The inner diameter dimension of the second via hole 131 on the planarization layer 13 is greater than an inner diameter dimension of the fourth via hole 141 on the fourth insulating layer 14, and the inner diameter dimension of the fourth via hole 141 is greater than the inner diameter dimension of the first via hole 111, so that a stepped structure is formed by the second via hole 131, the fourth via hole 141, and the first via hole 111 together, thereby improving the climbing stability of the first auxiliary electrode 51 inside the second via hole 131, the fourth via hole 141, and the first via hole 111.

The fourth insulating layer 14 is provided with a second other via hole 142 at a position corresponding to the drain contact part 313, and the second other via hole 142 is communicated with the first other via hole 132. An inner diameter dimension of the second other via hole 142 is less than an inner diameter dimension of the first other via hole 132. A part of the pixel electrode 52 is located inside the first other via hole 132 and the second other via hole 142 and connected to the drain contact part 313.

In one embodiment, referring to FIG. 1 and FIG. 2, FIG. 2 is a second schematic cross-sectional structural view of the array substrate according to an embodiment of the present application. Referring to FIG. 2, a difference from the embodiments mentioned above is that the array substrate 100 further includes an antioxidant layer 60 at least disposed at a connection position between the semiconductor layer 31 and the first conductive layer 20, so as to improve a connection reliability between the semiconductor layer 31 and the first conductive layer 20. It should be noted that when the first conductive layer 20 is made of the low-resistance material such as Al or Cu, the oxygen will participate when forming the semiconductor layer 31, which causes oxidation of the first conductive layer 20 by the oxygen, and further causes the poor overlapping between the semiconductor layer 31 and the first conductive layer 20. In this embodiment, the antioxidant layer 60 is provided at an overlapping position between the semiconductor layer 31 and the first conductive layer 20, and the semiconductor layer 31 overlaps the first conductive layer 20 through the antioxidant layer 60, so that the antioxidant layer 60 can protect the first conductive layer 20 from being oxidized, which causes the poor overlapping between the semiconductor layer 31 and the first conductive layer 20. The antioxidant layer 60 is made of titanium-molybdenum alloy or the like.

Specifically, referring to FIG. 2, taking that the source contact part 312 of the semiconductor layer 31 is connected to the source electrode 21 of the first conductive layer 20 as an example, the antioxidant layer 60 is disposed on the side of the source electrode 21 away from the substrate 10 and covers a surface of the source electrode 21. A part of the source contact part 312 covers the antioxidant layer 60 and is connected to the source electrode 21 through the antioxidant layer 60. The antioxidant layer 60 serves as a protective layer of the source electrode 21 to prevent the source electrode 21 from being oxidized and causing the poor overlapping between the source contact part 312 and the source electrode 21.

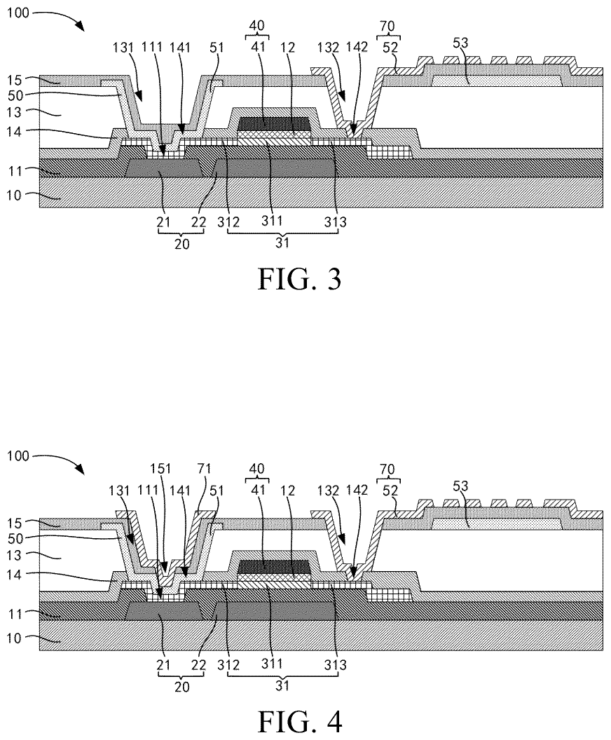

In one embodiment, referring to FIG. 1 to FIG. 3, FIG. 3 is a third schematic cross-sectional structural view of the array substrate according to an embodiment of the present application. Referring to FIG. 3, a difference from the embodiments mentioned above is that the array substrate 100 further includes a third insulating layer 15 and a fourth conductive layer 70. The fourth conductive layer 70 is disposed on a side of the third insulating layer 15 away from the substrate 10. The third conductive layer 50 includes the first auxiliary electrode 51 and a common electrode 53. The fourth conductive layer 70 includes a pixel electrode 52 opposite to the common electrode 53. The pixel electrode 52 is connected to the drain contact part 313 of the semiconductor layer 31. The first auxiliary electrode 51 is located inside the second via hole 131, the fourth via hole 141, and the first via hole 111. The first auxiliary electrode 51 is connected to the source contact part 312. A part of the third insulating layer 15 covers the first auxiliary electrode 51. In this embodiment, the third insulating layer 15 is made of an inorganic material, such as a plurality of layers or a single layer including at least one of tetraethyl orthosilicate, silicon nitride, silicon oxide, etc. The fourth conductive layer 70 may be made of a transparent conductive material, such as ITO, IZO, ZnO, In₂O₃, etc. Please refer to embodiments mentioned above for other descriptions, which will not be repeatedly described herein.

In some embodiments, referring to FIG. 1 to FIG. 4, FIG. 4 is a fourth schematic cross-sectional structural view of the array substrate according to an embodiment of the present application. Referring to FIG. 4, a difference from the embodiments mentioned above is that the third insulating layer 15 is disposed on a side of the third conductive layer 50 away from the substrate 10 and includes a third via hole 151 corresponding to the source contact part 312. The inner diameter dimension of the second via hole 131 is greater than the inner diameter dimension of the third via hole 151, and the inner diameter dimension of the third via hole 151 is greater than the inner diameter dimension of the first via hole 111. The fourth conductive layer 70 includes a second auxiliary electrode 71 and the pixel electrode 52. The second auxiliary electrode 71 is located inside the second via hole 131 and the third via hole 151 and connected to the first auxiliary electrode 51. By providing the second auxiliary electrode 71 on a side of the first auxiliary electrode 51 away from the source contact part 312, the second auxiliary electrode 71 covers the first auxiliary electrode 51 inside the third via hole 151 to improve an overlapping reliability between the first auxiliary electrode 51 and the source electrode 21, thereby further enhancing the overlapping reliability between the source contact part 312 and the source electrode 21, and further improving the problem of poor overlapping between the semiconductor layer 31 and the source electrode 21. Please refer to the embodiments mentioned above for other descriptions, which will not be repeatedly described herein.

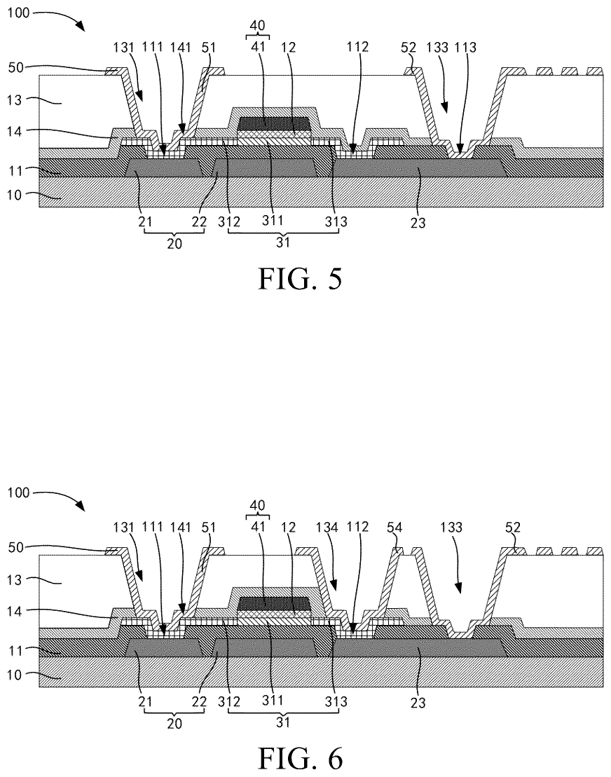

In some embodiments, referring to FIG. 1 to FIG. 5, FIG. 5 is a fifth schematic cross-sectional structural view of the array substrate according to an embodiment of the present application. Referring to FIG. 5, a difference from the embodiments mentioned above is that the first conductive layer 20 further includes a first bridge electrode 23, and the first insulating layer 11 further includes a fifth via hole 112 and a sixth via hole 113 corresponding to the first bridge electrode 23. The semiconductor layer 31 further includes the drain contact part 313 located at the side of the channel part 311 away from the source contact part 312. A part of the drain contact part 313 is disposed inside the fifth via hole 112 and connected to the first bridge electrode 23. The planarization layer 13 further includes a seventh via hole 133 corresponding to the first bridge electrode 23. The seventh via hole 133 corresponds to the sixth via hole 113, and the seventh via hole 133 is communicated with the sixth via hole 113. An inner diameter dimension of the seventh via hole 133 is greater than an inner diameter dimension of the sixth via hole 113. The pixel electrode 52 is located inside the seventh via hole 133 and the sixth via hole 113 and connected to the first bridge electrode 23.

It should be noted that when the pixel electrode 52 and/or the semiconductor layer 31 are made of a metal oxide, for example, when the pixel electrode 52 is made of indium tin oxide, and the semiconductor layer 31 is made of indium gallium zinc oxide, an impedance of the metal oxide itself is large, resulting in a larger overlapping impedance when the pixel electrode 52 and the drain contact part 313 of the semiconductor layer 31 are directly overlapped. In this embodiment, by providing the first bridge electrode 23, the pixel electrode 52 is connected to the drain contact part 313 of the semiconductor layer 31 through the first bridge electrode 23, so that the problem of large impedance when the pixel electrode 52 directly overlaps the drain contact part 313 can be improved. Please refer to the embodiments mentioned above for other descriptions, which will not be repeatedly described herein.

In one embodiment, referring to FIG. 1 to FIG. 6, FIG. 6 is a sixth schematic cross-sectional structural view of the array substrate according to an embodiment of the present application. Referring to FIG. 6, a difference from the embodiments mentioned above is that the array substrate 100 further includes a third auxiliary electrode 54 arranged in the same layer as the first auxiliary electrode 51. That is, the third conductive layer 50 further includes the third auxiliary electrode 54. The planarization layer 13 further includes an eighth via hole 134 corresponding to the drain contact part 313. The third auxiliary electrode 54 is disposed inside the eighth via hole 134 and connected to the drain contact part 313. An orthographic projection of the drain contact part 313 located inside the fifth via hole 112 on the substrate 10 is located within a range of an orthographic projection of the third auxiliary electrode 54 on the substrate 10, so that the third auxiliary electrode 54 completely covers the drain contact part 313 located inside the fifth via hole 112. As such, when the drain contact part 313 climbs and breaks inside the fifth via 112, the drain contact part 313 is continuous inside the fifth via hole 112, thereby enhancing an overlapping reliability between the drain contact part 313 and the first bridge electrode 21, and improving a problem of poor overlapping between the drain contact part 313 and the first bridge electrode 21. Please refer to the embodiments mentioned above for other descriptions, which will not be repeatedly described herein.

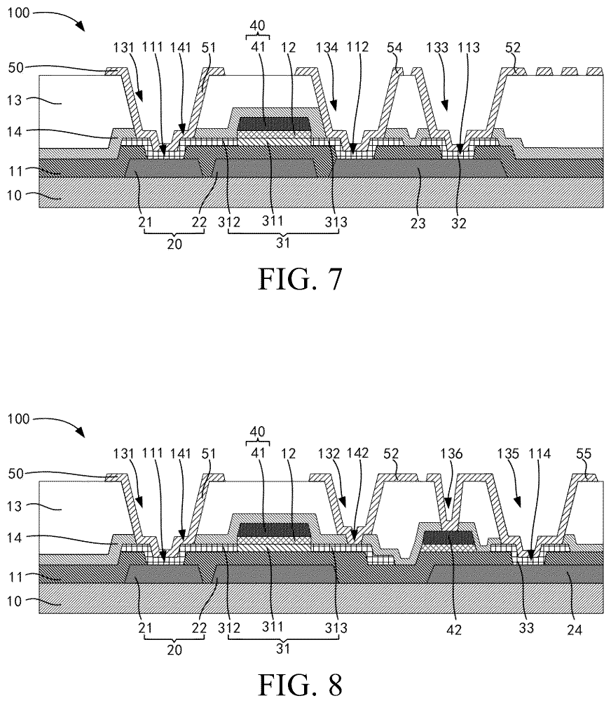

In one embodiment, referring to FIG. 1 to FIG. 7, FIG. 7 is a seventh schematic cross-sectional structural view of the array substrate according to an embodiment of the present application. Referring to FIG. 7, a difference from the embodiments mentioned above is that the array substrate 100 further includes a fifth auxiliary electrode 32. In this embodiment, the fifth auxiliary electrode 32 is arranged on the same layer as the semiconductor layer 31. The fifth auxiliary electrode 32 can be formed by conducting the semiconductor thin film. At least a part of the fifth auxiliary electrode 32 is disposed inside the sixth via hole 113 and connected to the first bridge electrode 23. The pixel electrode 52 is connected to the fifth auxiliary electrode 32 inside the sixth via hole 113 to improve the overlapping reliability between the pixel electrode 52 and the first bridge electrode 23.

It should be noted that during the process of directly overlapping the pixel electrode 52 and the first bridge electrode 23, the sixth via hole 113 is firstly necessary to be formed on the first insulating layer 11, and the sixth via hole 113 exposes at least a part of the first bridge electrode 23. Then, a semiconductor thin film is formed on the first insulating layer 11 and etched to form the semiconductor layer 31. However, during the process of etching the semiconductor thin film, the first bridge electrode 23 exposed by the damaged sixth via hole 113 may be damaged by an etching solution, which causes a problem of poor overlapping between the subsequent pixel electrode 52 and the first bridge electrode 23. In this embodiment, the semiconductor film is further formed with the fifth auxiliary electrode 32 when the semiconductor layer 31 is formed by etching the semiconductor film, so that the pixel electrode 52 can be connected to the first bridge electrode 23 through the fifth auxiliary electrode 32, thereby improving the problem of poor overlapping when the pixel electrode 52 and the first bridge electrode 23 are directly overlapped, and improving the overlapping reliability between the pixel electrode 52 and the first bridge electrode 23. In addition, in this embodiment, by providing the fifth auxiliary electrode 32 inside the sixth via hole 113 formed in the first insulating layer 11, the pixel electrode 52 is connected to the fifth auxiliary electrode 32 inside the sixth via hole 113, thereby increasing a contact area between the pixel electrode 52 and the fifth auxiliary electrode 32, and reducing a contact impedance between the pixel electrode 52 and the fifth auxiliary electrode 32. In other words, by providing the fifth auxiliary electrode 32, the problem of poor overlapping between the pixel electrode 52 and the first bridging electrode 23 can be improved without affecting the effect of improving the impedance problem of direct overlapping between the pixel electrode 52 and the drain contact portion 313. Please refer to the embodiments mentioned above for other descriptions, which will not be repeatedly described herein.

In some embodiments, referring to FIG. 1 to FIG. 8, FIG. 8 is an eighth schematic cross-sectional structural view of the array substrate according to an embodiment of the present application. Referring to FIG. 8, a difference from the embodiments mentioned above is that the first conductive layer 20 further includes a first signal line 24, and the second conductive layer 40 further includes a second signal line 42. The planarization layer 13 further includes a ninth via hole 135 corresponding to the first signal line 24 and a tenth via hole 136 corresponding to the second signal line 42. The first insulating layer 11 further includes a third other via hole 114 corresponding to the first signal line 24. The third other via hole 114 is disposed opposite to and communicated with the ninth via hole 135. An inner diameter dimension of the ninth via hole 135 is greater than the inner diameter dimension of the third other via hole 114. The array substrate 100 further includes a second bridge electrode 55 arranged in the same layer as the first auxiliary electrode 51. A part of the second bridge electrode 55 is disposed inside the ninth via hole 135 and connected to the first signal line 24. Another part of the second bridge electrode 55 is disposed inside the tenth via hole 136 and connected to the second signal line 42, so that the first signal line 24 is connected to the second signal line 42 through the second bridge electrode 55.

In some embodiments, the array substrate 100 further includes a fourth auxiliary electrode 33. In this embodiment, the fourth auxiliary electrode 33 is arranged in the same layer as the semiconductor layer 31, and the fourth auxiliary electrode 33 may be formed by conducting the semiconductor thin film. At least part of the fourth auxiliary electrode 33 is disposed inside the third other via hole 114 and connected to the first signal line 24, and the second bridge electrode 55 is connected to the fourth auxiliary electrode 33 inside the third other via hole 114 to improve an overlapping reliability between the fourth auxiliary electrode 33 and the first signal line 24. Please refer to the embodiments mentioned above for other descriptions, which will not be repeatedly described herein.

Based on a same inventive concept, the present application also provides a display panel including the array substrate 100 according to any one of the embodiments mentioned above. The display panel includes a liquid crystal display panel, an organic light emitting diode display panel, etc.

According to the above embodiments, it can be seen that: in the array substrate and the display panel provided by the present application, the array substrate includes the substrate and the substrate, the first conductive layer, the semiconductor layer, the second insulating layer, the second conductive layer, the planarization layer, and the third conductive layer disposed on the substrate. The first conductive layer is disposed on the side of the substrate and includes the source electrode and the light shielding electrode arranged at intervals. The semiconductor layer includes the channel part and the source contact part located at the side of the channel part. The part of the source contact part is disposed inside the first via hole and connected to the source electrode. The third conductive layer is disposed on the side of the planarization layer away from the substrate and includes the first auxiliary electrode corresponding to the source contact part. The first auxiliary electrode is connected to at least the source contact part located inside the first via hole. The orthographic projection of the source contact part located inside the first via hole on the substrate is within the range of the orthographic projection of the first auxiliary electrode on the substrate, so that the first auxiliary electrode can completely cover the source contact part located inside the first via hole. As such, the first auxiliary electrode can fill a position where the source contact part is broken when the source contact part climbs and breaks inside the first via, so that the source contact part is continuous inside the first via, thereby enhancing an overlapping reliability between the source contact part and source electrode, and improving a problem of poor overlapping between the semiconductor layer and the source electrode.

In the embodiments mentioned above, the description of each embodiment has its own emphasis, and for parts not described in detail in a certain embodiment, please refer to the related description of other embodiments.

The embodiments of the present application are described in detail above. The principle and implementations of the present application are described in this specification by using specific examples. The description about the foregoing embodiments is merely provided to help understand the method and core ideas of the present application. Persons of ordinary skill in the art should understand that they may still make modifications to the technical solutions described in the foregoing embodiments or make equivalent replacements to some or all technical features thereof, without departing from the scope of the technical solutions of the embodiments of the present application.

What is claimed is:

1. An array substrate comprising:
a substrate;
a first conductive layer disposed on a side of the substrate and comprising a source electrode and a light shielding electrode arranged at intervals;
a first insulating layer disposed on a side of the first conductive layer away from the substrate and comprising a first via hole corresponding to the source electrode;
a semiconductor layer disposed on a side of the first insulating layer away from the substrate, wherein the semiconductor layer comprises a channel part and a source contact part located on a side of the channel part, a part of the source contact part is disposed inside the first via hole and connected to the source electrode, and the channel part corresponds to the light shielding electrode;
a second insulating layer disposed on the semiconductor layer and corresponding to the channel part;
a second conductive layer disposed on the second insulating layer and comprising a gate electrode;
a planarization layer disposed on a side of the second conductive layer away from the substrate and comprising a second via hole corresponding to the source contact part; and
a third conductive layer disposed on a side of the planarization layer away from the substrate and comprising a first auxiliary electrode corresponding to the source contact part, wherein the first auxiliary electrode is connected to at least the source contact part located inside the first via hole, and an orthographic projection of the source contact part located inside the first via hole on the substrate is within a range of an orthographic projection of the first auxiliary electrode on the substrate.

2. The array substrate according to claim 1, wherein the first auxiliary electrode is disposed inside the second via hole and the first via hole and connected to the source contact part, and the third conductive layer further comprises a pixel electrode.

3. The array substrate according to claim 1, wherein the first auxiliary electrode is disposed inside the second via hole and the first via hole and connected to the source contact part, and the third conductive layer further comprises a common electrode.

4. The array substrate according to claim 3, further comprising:
a third insulating layer disposed on a side of the third conductive layer away from the substrate and comprising a third via hole corresponding to the source contact part; and
a fourth conductive layer disposed on a side of the third insulating layer away from the substrate and comprising a second auxiliary electrode and a pixel electrode, wherein the second auxiliary electrode is located inside the second via hole and the third via hole and connected to the first auxiliary electrode.

5. The array substrate according to claim 4, wherein an inner diameter dimension of the second via hole is greater than an inner diameter dimension of the third via hole, and the inner diameter dimension of the third via hole is greater than an inner diameter dimension of the first via hole.

6. The array substrate according to claim 4, further comprising:
a fourth insulating layer disposed on a side of the gate electrode away from the substrate and comprising a fourth via hole corresponding to the source contact part, wherein the first auxiliary electrode is further disposed inside the fourth via hole;
wherein the planarization layer is disposed on a side of the fourth insulating layer away from the substrate, and an inner diameter dimension of the second via hole is greater than an inner diameter dimension of the fourth via hole.

7. The array substrate according to claim 6, wherein the first conductive layer further comprises a first bridge electrode, and the first insulating layer further comprises a fifth via hole and a sixth via hole corresponding to the first bridge electrode;
the semiconductor layer further comprises a drain contact part located at a side of the channel part away from the source contact part, and a part of the drain contact part is disposed inside the fifth via hole and connected to the first bridge electrode; and
the planarization layer further comprises a seventh via hole corresponding to the first bridge electrode, and the pixel electrode is located inside the seventh via hole and the sixth via hole and connected to the first bridge electrode.

8. The array substrate according to claim 7, wherein the third conductive layer further comprises a third auxiliary electrode, the planarization layer further comprises an eighth via hole corresponding to the drain contact part, the third auxiliary electrode is disposed inside the eighth via hole and connected to the drain contact part, and an orthographic projection of the drain contact part located inside the fifth via hole on the substrate is within a range of an orthographic projection of the third auxiliary electrode on the substrate.

9. The array substrate according to claim 6, wherein the first conductive layer further comprises a first signal line, and the second conductive layer further comprises a second signal line;
the planarization layer further comprises a ninth via hole corresponding to the first signal line and a tenth via hole corresponding to the second signal line; and
the array substrate further comprises a second bridge electrode arranged in the same layer as the first auxiliary electrode, one part of the second bridge electrode is disposed inside the ninth via hole and connected to the first signal line, and the other part of the second bridge electrode is disposed inside the tenth via hole and connected to the second signal line.

10. The array substrate according to claim 9, further comprising a fourth auxiliary electrode connected to the first signal line, wherein the second bridge electrode is connected to the fourth auxiliary electrode, and the fourth auxiliary electrode is arranged in the same layer as the semiconductor layer.

11. The array substrate according to claim 6, further comprising an antioxidant layer at least disposed at a connection position between the semiconductor layer and the first conductive layer.

12. The array substrate according to claim 2, further comprising:
a fourth insulating layer disposed on a side of the gate electrode away from the substrate and comprising a fourth via hole corresponding to the source contact part, wherein the first auxiliary electrode is further disposed inside the fourth via hole;
wherein the planarization layer is disposed on a side of the fourth insulating layer away from the substrate, and an inner diameter dimension of the second via hole is greater than an inner diameter dimension of the fourth via hole.

13. The array substrate according to claim 12, wherein the first conductive layer further comprises a first bridge electrode, and the first insulating layer further comprises a fifth via hole and a sixth via hole corresponding to the first bridge electrode;
the semiconductor layer further comprises a drain contact part located at a side of the channel part away from the source contact part, and a part of the drain contact part is disposed inside the fifth via hole and connected to the first bridge electrode; and
the planarization layer further comprises a seventh via hole corresponding to the first bridge electrode, and the pixel electrode is located inside the seventh via hole and the sixth via hole and connected to the first bridge electrode.

14. The array substrate according to claim 13, wherein the third conductive layer further comprises a third auxiliary electrode, the planarization layer further comprises an eighth via hole corresponding to the drain contact part, the third auxiliary electrode is disposed inside the eighth via hole and connected to the drain contact part, and an orthographic projection of the drain contact part located inside the fifth via hole on the substrate is within a range of an orthographic projection of the third auxiliary electrode on the substrate.

15. The array substrate according to claim 12, wherein the first conductive layer further comprises a first signal line, and the second conductive layer further comprises a second signal line;
the planarization layer further comprises a ninth via hole corresponding to the first signal line and a tenth via hole corresponding to the second signal line; and
the array substrate further comprises a second bridge electrode arranged in the same layer as the first auxiliary electrode, one part of the second bridge electrode is disposed inside the ninth via hole and connected to the first signal line, and the other part of the second bridge electrode is disposed inside the tenth via hole and connected to the second signal line.

16. The array substrate according to claim 15, further comprising a fourth auxiliary electrode connected to the first signal line, wherein the second bridge electrode is connected to the fourth auxiliary electrode, and the fourth auxiliary electrode is arranged in the same layer as the semiconductor layer.

17. The array substrate according to claim 12, further comprising an antioxidant layer at least disposed at a connection position between the semiconductor layer and the first conductive layer.

18. A display panel comprising an array substrate, wherein the array substrate comprises:
a substrate;
a first conductive layer disposed on a side of the substrate and comprising a source electrode and a light shielding electrode arranged at intervals;
a first insulating layer disposed on a side of the first conductive layer away from the substrate and comprising a first via hole corresponding to the source electrode;
a semiconductor layer disposed on a side of the first insulating layer away from the substrate, wherein the semiconductor layer comprises a channel part and a source contact part located on a side of the channel part, a part of the source contact part is disposed inside the first via hole and connected to the source electrode, and the channel part corresponds to the light shielding electrode;
a second insulating layer disposed on the semiconductor layer and corresponding to the channel part;
a second conductive layer disposed on the second insulating layer and comprising a gate electrode;
a planarization layer disposed on a side of the second conductive layer away from the substrate and comprising a second via hole corresponding to the source contact part; and
a third conductive layer disposed on a side of the planarization layer away from the substrate and comprising a first auxiliary electrode corresponding to the source contact part, wherein the first auxiliary electrode is connected to at least the source contact part located inside the first via hole, and an orthographic projection of the source contact part located inside the first via hole on the substrate is within a range of an orthographic projection of the first auxiliary electrode on the substrate.

19. The display panel according to claim 18, wherein the first auxiliary electrode is disposed inside the second via hole and the first via hole and connected to the source contact part, and the third conductive layer further comprises a pixel electrode.

20. The display panel according to claim 18, wherein the first auxiliary electrode is disposed inside the second via hole and the first via hole and connected to the source contact part, and the third conductive layer further comprises a common electrode.
